(19) United States
(12) Patent Application Publication
(10) Pub. No.: US 2025/0305112 A1
(43) Pub. Date: Oct. 2, 2025

(54) TUNGSTEN TARGET AND METHOD FOR MANUFACTURING SAME

(71) Applicant: Ulvac, Inc., Chigasaki-shi, Kanagawa (JP)

(72) Inventors: Ryota NAKAMURA, Chigasaki-shi (JP); Taku OKUBO, Chigasaki-shi (JP); Kazuma SHIBASAKI, Chigasaki-shi (JP); Taiga SAKAMOTO, Chigasaki-shi (JP); Naoto TEZUKA, Chigasaki-shi (JP)

(21) Appl. No.: 18/861,834

(22) PCT Filed: Jun. 7, 2023
(86) PCT No.: PCT/JP2023/021157

§ 371 Date: Jun. 13, 2025

(30) Foreign Application Priority Data
Jun. 27, 2022 (JP) 2022-103074

(51) Int. Cl. C23C 14/34

(52) U.S. Cl. CPC C23C 14/3414

(57) ABSTRACT

To provide a tungsten target in which provision of pores which may cause generation of particles is suppressed, and the size and distribution profile of the pores can be controlled at high precision, and a method for producing the tungsten target. The tungsten target is formed of a sintered product of a tungsten powder. The target has a relative density of 99% or higher, and the number of pores having a size of 0.01 μm² or more and less than 0.2 μm² is 20 or less; the number of pores having a size of 0.2 μm² or more and less than 1.8 μm² is 5 or less; and the number of pores having a size of 1.8 μm² or more is 1 or less, when the target is observed in an observation field of 0.15 mm².

### TECHNICAL FIELD

The present invention relates to a tungsten target formed of a sintered product of a tungsten powder, and to a method for producing the target.

### BACKGROUND ART

In recent years, tungsten, which has heat resistance and a low-resistance characteristic, is widely used as a wiring material or an electrode material for producing semiconductor devices. Generally, tungsten film is formed through a sputtering technique. In formation of tungsten film through sputtering, argon ions generated through plasma discharge are caused to collide with a tungsten target, to thereby hit out tungsten atoms from the surface of the target, and the thus-released tungsten atoms are deposited on a substrate facing the target. In this process, particles originating from the surface of the target are deposited on the substrate, resulting in a drop in yield of the tungsten film. The phenomenon is known to be a grave problem in the above process. Therefore, the tungsten target is essentially required to produce considerably small amounts of such particles and to have minute and uniform crystal grains and a high relative density.

For example, Patent Document 1 discloses a method for producing a tungsten target in which a very small amount of molybdenum is added to a tungsten powder in order to prevent generation of particles. According to the method, a target having a relative density of 95% or more and a mean grain size of 10 μm to 300 μm (inclusive) can be produced.

Patent Document 2 discloses a method for producing a sputtering target, the method sequentially comprising filling a metal capsule with tungsten powder; pressing the powder at ambient temperature; conducting encapsulation in vacuum; and subjecting the resultant capsule to a hot isostatic pressing (HIP) sintering treatment. According to the method, there can be produced a tungsten target which has a mean grain size of 20 μm to 100 μm, a relative density of 99% or more, and an oxygen content of 10 ppm by mass (hereinafter referred to simply as “mass ppm”) to 15 mass ppm.

However, according to conventional tungsten target production methods, variation in crystal grain size is not negligible, and the mean grain size cannot be controlled to a uniformly small value not more than some tens of micrometers. Thus, the effect of preventing generation of particles during sputtering is not sufficiently achieved, and the yield of the tungsten target decreases.

In order to solve the problems, there was previously proposed a method for producing a tungsten target, which method can control the mean grain size to some tens of micrometers or less. The proposed production method includes a step of producing a preform of a tungsten powder having a relative density of 70% to 90% and an oxygen content of 100 mass ppm to 500 mass ppm, wherein the preform is sintered through hot isostatic pressing at 1, 700° C. to 1,850° C. (see Patent Document 3).

### PRIOR ART DOCUMENTS

### Patent Documents

Patent Document 1: Japanese Patent Application Laid-Open (kokai) No. 2001-295036
Patent Document 2: Japanese Patent Application Laid-Open (kokai) No. 2003-193225
Patent Document 3: WO 2012/042791

### SUMMARY OF THE INVENTION

### Problems to be Solved by the Invention

In the trend for minimizing the dimensions of wirings and the like employing tungsten, particles originating from the tungsten target detrimentally affect the yield of tungsten film. Accordingly, there is demand for further suppression of undesired particle generation. Also, hot isostatic pressing employing CAN unavoidably includes considerably cumbersome steps, resulting in low productivity. Thus, employment of the method is not motivated. Furthermore, crystal grain size may be excessively small, to thereby possibly induce a drop in film formation speed.

Under such circumstances, the present inventors previously pursued the role of the particles in forming a tungsten target through sputtering. As a result, the target produced through the aforementioned method inevitably included pores, even though the relative density of the sintered product reached about 100% or less. In addition, since the size and distribution profile of the pores are not controlled, generation of particles cannot be suppressed, thereby possibly reducing the yield.

Thus, in order to enhance the yield of a tungsten target, there is sought a tungsten target in which generation of particles is suppressed to a maximum extent as possible. Consequently, a method for producing such a tungsten target is required.

The present invention has been conceived in view of the foregoing. Thus, an object of the present invention is to provide a tungsten target in which provision of pores which may cause generation of particles is suppressed, and the size and distribution profile of the pores can be controlled at high precision. Another object is to provide a method for producing the tungsten target.

### Means for Solving the Problems

In a first mode of the present invention for attaining the aforementioned objects, there is provided a tungsten target formed of a sintered product of a tungsten powder, wherein the target has a relative density of 99% or higher, and the number of pores having a size of 0.01 μm² or more and less than 0.2 μm² is 20 or less; the number of pores having a size of 0.2 μm² or more and less than 1.8 μm² is 5 or less; and the number of pores having a size of 1.8 μm² or more is 1 or less, when the target is observed in an observation field of 0.15 mm².

A second mode of the present invention is directed to a specific embodiment of the tungsten target of the first mode, wherein the target has a mean value of Vickers hardness of 355 to 375.

A third mode of the present invention is directed to a specific embodiment of the tungsten target of the second mode, wherein the target has a ratio of the standard deviation 3σ of Vickers hardness to the mean value of Vickers hardness of 0.07 or less.

A fourth mode of the present invention is directed to a specific embodiment of the tungsten target of any of the first to third modes, wherein the target has a mean grain size calculated on the basis of the circle-equivalent diameter of 150 μm or less.

A fifth mode of the present invention is directed to a specific embodiment of the tungsten target of the fourth mode, wherein the target has a ratio of the standard deviation 3σ of the grain size calculated on the basis of the circle-equivalent diameter to the mean grain size of 1.5 or less.

In a sixth mode of the present invention for attaining the aforementioned objects, there is provided a method for producing a tungsten target, the method comprising:
hot pressing a tungsten powder at 1,400° C. to 1,500° C., wherein the powder has a mean particle size as determined through a laser diffraction scattering method of 3 μm or less and a median diameter D50 as determined through a laser diffraction scattering method of 2.8 μm or less; and
subsequently, sintering the pressed product through hot isostatic pressing at 1,800° C. to 1,850° C.

A seventh mode of the present invention is directed to a specific embodiment of the tungsten target production method of the sixth mode, wherein the tungsten powder has a ratio of D90 as determined through a laser diffraction scattering method to the mean particle size as determined through a laser diffraction scattering method of 2.5 or less.

An eighth mode of the present invention is directed to a specific embodiment of the tungsten target production method of the sixth or seventh mode, wherein the tungsten powder has a ratio of D95 as determined through a laser diffraction scattering method to the mean particle size as determined through a laser diffraction scattering method of 3.0 or less.

### BRIEF DESCRIPTION OF THE DRAWINGS

FIG. 1 A graph showing the relationship between the number of pores having a size of 0.01 to 0.2 μm² (Examples of the present invention and Comparative Examples) and the number of particles.

FIG. 2 A graph showing the relationship between the number of pores having a size of 0.2 to 1.8 μm² (Examples of the present invention and Comparative Examples) and the number of particles.

FIG. 3 A graph showing the relationship between the number of pores having a size of ≥1.8 μm² (Examples of the present invention and Comparative Examples) and the number of particles.

### MODES FOR CARRYING OUT THE INVENTION

The tungsten target of the present invention has a tungsten purity of 5N (99.999 mass %) or higher; a carbon content and an oxygen content (both elements are impurities present in tungsten) of 30 mass ppm or less, respectively; and a mean grain size of 150 μm or less.

### (Purity)

In order to form a tungsten film having low specific resistance (or resistivity), the impurity level of the tungsten film must be minimized. Thus, the purity of the tungsten target must be elevated. Specifically, a purity of 99.999 mass % (5N) or higher is required.

### (Gas Components)

gas components such as carbon and oxygen present in the tungsten target adversely impair the specific resistance of the tungsten film. These gas components are unavoidably incorporated into the tungsten film during film formation. As the components content increases, the specific resistance of the tungsten film tends to increase. Therefore, the carbon content of the tungsten target is preferably 20 mass ppm or less, more preferably 10 mass ppm or less. The oxygen content is preferably 30 mass ppm or less, more preferably 20 mass ppm or less.

### (Crystal Grain Size)

In the tungsten target of the present invention, the mean crystal grain size calculated on the basis of the circle-equivalent diameter is preferably 10 μm to 150 μm, more preferably 30 μm to 100 μm.

The reasons for controlling the mean crystal grain size (mean grain diameter) are as follows.

Specifically, as the mean grain size of the tungsten target decreases, variation in erosion amount of the target, which is attributed to variation in orientation of crystal grains present on the surface of the target, can be reduced. As a result, anomalous discharge attributed to the roughness of the surface can be suppressed, whereby generation of particles during film formation can be suppressed.

In contrast, when the mean grain size is controlled to be excessively small, film formation rate excessively decreases, thereby lowering productivity.

Also, the ratio of the triple standard deviation (3σ) of the grain size calculated on the basis of the circle-equivalent diameter to the mean grain size is 1.5 or less. The ratio is calculated by dividing standard deviation 3σ by mean grain size.

The reason why the ratio is preferably 1.5 or less is as follows.

Specifically, variation in crystal grain size correlates with the number and size of pores. As variation in crystal grain size decreases, the number and size of the pores in the target are reduced. Thus, when the ratio falls within the above range, generation of particles during film formation can be suppressed.

### (Relative Density)

The relative density of the tungsten target is preferably tuned to 99% or more. When the target has a relative density of 99% or more, the gas-generating component content of the target is small. Thus, a rise in specific resistance of a film can be suppressed during formation of the film. Also, the higher the relative density of the target, the fewer the number of pores. As a result, anomalous discharge attributed to the roughness of the surface can be suppressed, whereby generation of particles during film formation can be suppressed.

### (Vickers Hardness)

The mean value of Vickers hardness of the tungsten target is preferably 355 to 375.

A mean value of Vickers hardness falling within the above range is preferred for the following reason.

Specifically, the mean value of Vickers hardness correlates with the number and size of pores present in the target. The greater the mean value of Vickers hardness, the smaller the number and size of pores in the target. Thus, generation of particles during film formation can be suppressed.

In contrast, when the mean hardness is excessively high, an appropriate heat treatment cannot be completed, and difficulty is encountered in releasing the internal strain of the target. In such a case, the target may possibly be cracked from the internal strain by thermal stress applied during processing to form the target or film formation through sputtering.

Meanwhile, the ratio of the triple standard deviation (3σ) of Vickers hardness to the mean value of Vickers hardness is 0.07 or less. The ratio is calculated by dividing standard deviation (3σ) by mean value of Vickers hardness.

A ratio of the triple standard deviation (3σ) of Vickers hardness to the mean value of Vickers hardness falling with in the above range is preferred from the following reason.

Specifically, variation in Vickers hardness correlates with the number and size of pores present in the target. The smaller the variation in Vickers hardness, the smaller the number and size of the pores in the target. Thus, generation of particles during film formation can be suppressed.

### (Pores)

In the tungsten target of the present invention, the number of pores having a size of 0.01 μm² or more and less than 0.2 μm² is 20 or less; the number of pores having a size of 0.2 μm² or more and less than 1.8 μm² is 5 or less; and the number of pores having a size of 1.8 μm² or more is 1 or less, when the target is observed in an observation field of 0.15 mm².

In the present invention, the reason for regulating the size and number of pores is as follows.

By controlling the size and number of pores present in the target, the electric field is focused to the pores, whereby formation of particles, which would otherwise occur by local dissolution and scattering, can be suppressed, to thereby enhance the yield of the tungsten film. In addition, since generation of particles can be continuously suppressed to the life-end of the target, tungsten film can be consistently produced.

Hitherto, there has not been realized a tungsten target which includes only a small number of coarse pores and in which localization of pores is suppressed along the plane and thickness directions. However, such a tungsten target can be first obtained on the basis of the aforementioned unique characteristics in terms of relative density, hardness, and crystal grain size. Also, the tungsten target of the present invention which includes only a small number of coarse pores and in which localization of pores is suppressed along the plane and thickness directions can be produced through the below-mentioned production method.

As described above, the aforementioned tungsten target of the present invention has few pores with a small size. Thus, by use of the tungsten target, generation of particles can be remarkably reduced, and a high-quality tungsten film can be consistently formed.

Next will be described an embodiment of the method for producing the tungsten target of the present invention.

The tungsten target of the present invention can be produced by hot pressing a tungsten powder at 1,400° C. to 1,500° C., wherein the powder has a mean particle size, as determined through a laser diffraction scattering method, of 3 μm or less and a median diameter D50 of 2.8 μm or less (i.e., HP step); and subsequently, sintering the pressed product through hot isostatic pressing at 1,800° C. to 1,850° C. (i.e., HIP step).

In the sputtering target production method of the present invention, a first key feature is use of a tungsten powder having a mean particle size of 3 μm or less, preferably 2.8 μm or less, and a D50 of 2.8 μm or less, preferably 2.5 μm or less.

The oxygen content of a raw material powder may determine the oxygen content of the tungsten target. Therefore, the oxygen content of a raw material powder is controlled to, for example, 1,000 mass ppm or less.

A second key feature of the sputtering target production method of the present invention is use of a tungsten powder having a value obtained by dividing D90 as determined through a laser diffraction scattering method by the mean particle size of 2.5 or less, preferably 2.3 or less.

Also, a third key feature of the sputtering target production method of the present invention is use of a tungsten powder having a value obtained by dividing D95 as determined through a laser diffraction scattering method by the mean particle size of 3 or less, preferably 2.8 or less.

As described above, a tungsten target having a considerably small number and size of pores can be produced by use of a tungsten powder having a considerably narrow particle size distribution (i.e., a small variation in particle size from the mean particle size). In the present invention, a characteristic of such a narrow particle size distribution is defined by a value obtained by dividing D90 as determined through a laser diffraction scattering method by the mean particle size, or a value obtained by dividing D95 as determined through a laser diffraction scattering method by the mean particle size, being a specific level or less. Notably, a tungsten powder having a particle size distribution falling outside the above range cannot exert the advantageous effect of the present invention.

The sputtering target of the present invention can be produced by hot pressing the above-described tungsten powder at 1,400° C. to 1,500° C., and subsequently, sintering the pressed product through hot isostatic pressing at 1,800° C. to 1,850° C.

Through hot pressing in high vacuum, degassing and sintering are promoted, whereby a high-density sintered product can be yielded while the oxygen content of the tungsten target is reduced. When the tungsten powder contains a large amount of oxygen, the amount of oxide in the tungsten target increases, and generation of particles is more frequently evoked. In addition, a thick surface oxide film impedes sintering, thereby failing to yield a high-density sintered product.

As described above, the gas-forming components (e.g., carbon and oxygen) present in the tungsten target adversely impair the specific resistance of the formed tungsten film. Thus, the carbon content of the tungsten target is preferably 20 mass ppm or less, more preferably 10 mass ppm or less. The oxygen content is preferably 30 mass ppm or less, more preferably 20 mass ppm or less. As described above, such a low oxygen content can be achieved through vacuum hot pressing.

The carbon concentration increases for the following reason. In hot pressing, carbon diffuses from a graphite member of a hot press apparatus to a sintered product of tungsten, and the thus-migrated carbon elevates the carbon content. Therefore, the temperature of hot pressing is preferably lower. When the temperature is 1,500° C., a carbon content of 20 mass ppm or less, suitably 10 mass ppm or less, can be consistently attained.

In the HP step, a sintered product having a relative density of 95% or higher is produced. For producing a sintered product having such a property, the temperature of HP is preferably 1,400° C. to 1,500° C. When the HP temperature is excessively low, a density which allows HIP treatment cannot be achieved, whereas when the temperature is excessively high, undesirably rapid grain growth occurs to locally provide coarse pores. Both cases are not preferred. When the pressure of HP is excessively low, a density which allows HIP treatment cannot be achieved, whereas when the pressure is excessively high, damage of the HP apparatus proceeds rapidly. In one case, the pressure of HP treatment is 39.2 MPa (400 kg/cm²) to 44.1 MPa (450 kg/cm²). The HP retention time in the step is 600 minutes to 1,200 minutes. When the HP retention time is too short, a density which allows HIP treatment cannot be achieved, whereas when the retention time is excessively long, productivity decreases. In the present invention, essentially, the particle size and its distribution of the powder are controlled; and the HP temperature and retention time are regulated to 1,400° C. to 1,500° C. and 600 minutes to 1,200 minutes, respectively. Through this tuning, provision of more coarse pores in the sintered product can be suppressed, to thereby uniformly disperse minute pores in the sintered body.

In order to reduce pores in the sintered product which has undergone HP treatment, hot isostatic pressing (HIP) is performed to achieve high density.

The HIP temperature is 1,800° C. to 1,850° C. When the HIP temperature is lower than 1,800° C., difficulty is encountered in achievement of a relative density as high as 99% within a process time suited for mass production due to the low treatment temperature. When the HIP temperature is higher than 1,850° C., undesirably rapid crystal grain growth occurs to locally provide coarse pores, due to the high treatment temperature, which is not preferred. No particular limitation is imposed on the pressure of HIP, and it is, for example, 100 to 200 MPa. In this embodiment, the pressure is 176.4 MPa (1,800 kg/cm²).

According to the aforementioned production method, a tungsten target having characteristics of the present invention can be yielded. Particularly, the number and size of the pores possibly present in the tungsten target can be reduced, and localization of the pores can be suppressed. Thus, by use of the sputtering target of the present embodiment, generation of particles during film formation can be reduced, to thereby consistently form a high-quality tungsten film.

Generally, the presence of pores in a sputtering target strongly correlates with the particle size and its distribution of a raw material powder, the relative density of the sintered product, the crystal grain size and its distribution of the target, and the hardness and its distribution of the target. In the case in which the particle size of a raw material powder is smaller; its distribution width is narrower; the relative density of the sintered product is higher; variation in crystal grain size of the sintered product is smaller, or variation in hardness of the sintered product is smaller, provision of pores can be remarkably reduced, and the size of each pore remarkably decreases.

Even though the crystal grain size is very small, when variation in grain size is large, provision of coarse pores cannot be inhibited. According to the present inventors' finding, the particle size of a raw material powder, its distribution width, hot pressing conditions, and hot isostatic pressing conditions are optimized, whereby the relative density of the sintered product is enhanced, and variations in crystal grain size and hardness are suppressed. As a result, the tungsten target of the present invention, having very few coarse pores without substantial localization, can be produced.

Briefly, according to the tungsten target production method in the present embodiment, a raw material powder is hot-pressed at 1,400° C. to 1,500° C. and, subsequently, the pressed product is sintered through hot isostatic pressing at 1,800° C. to 1,850° C.

According to the above-described tungsten target production method, the size and number pores present in the produced sputtering target are very small. For example, the above production method enables consistent production of a tungsten target, in which the number of pores having a size of 0.01 μm² or more and less than 0.2 μm² is 20 or less; the number of pores having a size of 0.2 μm² or more and less than 1.8 μm² is 5 or less; and the number of pores having a size of 1.8 μm² or more is 1 or less, when the target is observed in an observation field of 0.15 mm².

Also, the above-described tungsten target production method enables consistent and efficient production of a tungsten target, which has a relative density of 99% or higher; a Vickers hardness of 355 to 375; a ratio of the standard deviation 3σ of Vickers hardness to the mean value of Vickers hardness of 0.07 or less; a mean grain size of 150 μm or less; or a ratio of the standard deviation 3σ of the mean grain size to the mean grain size of 1.5 or less.

According to the production method, a tungsten target in which the size and number of pores are small can be produced. By use of the tungsten target, generation of particles can be remarkably reduced, and a high-quality tungsten film can be consistently formed.

The thus-fabricated sintered product is processed into a target shape of interest in a processing step. No particular limitation is imposed on the processing method, but mechanical processing techniques such as grinding and cutting are typically employed. The dimensions and shape in processing are determined in accordance with specifications of the target to be produced. The shape is, for example, circular or rectangular. The thus-processed sintered product is joined to a backing plate, to thereby fabricate a sputtering cathode.

### EXAMPLES

The present invention will next be described in detail by way of the Examples and Comparative Examples.

Notably, the mean particle size and its distribution of each tungsten powder were determined by means of a particle size distribution meter “LS13320,” product of MicrotrackBEL Corp.

### Examples 1 to 5

A tungsten powder (purity: 5N) having characteristics shown in Table 1 was hot-pressed at a temperature as shown in Table 1 and falling within a range of 1,400° C. to 1,500° C. The characteristics of the powder were as follows: a mean particle size as determined through a laser diffraction scattering method of 3 μm or less; a median diameter D50 as determined through a laser diffraction scattering method of 2.8 μm or less; a value obtained by dividing D90 by the mean particle size of 2.5 or less; and a value obtained by dividing D95 by the mean particle size of 3 or less. Subsequently, the pressed product was subjected to HIP at a temperature shown in Table 1 and falling within a range of 1,800° C. to 1,850° C., to thereby yield a sintered product of tungsten. The thus-obtained tungsten sintered product was subjected to grinding by means of a lathe, to thereby form a tungsten target of a specific shape (diameter: 440 mm, thickness: 6 mm).

### Comparative Example 1

A tungsten powder (purity: 5N) having characteristics shown in Table 1 was hot-pressed at 1,750° C. as shown in Table 1. The characteristics of the powder were as follows: a mean particle size as determined through a laser diffraction scattering method of 3 μm or more; a median diameter D50 as determined through a laser diffraction scattering method of 2.8 μm or more; a value obtained by dividing D90 by the mean particle size of 2.5 or more; and a value obtained by dividing D95 by the mean particle size of 3 or more. Subsequently, the pressed product was subjected to HIP at 1,750° C. in Table 1, to thereby yield a sintered product of tungsten. The thus-obtained tungsten sintered product was subjected to grinding by means of a lathe, to thereby form a tungsten target of a specific shape (diameter: 440 mm, thickness: 6 mm).

### Comparative Example 2

A tungsten powder (purity: 5N) having characteristics shown in Table 1 was hot-pressed at 1,750° C. as shown in Table 1. The characteristics of the powder were as follows: a mean particle size as determined through a laser diffraction scattering method of 3 μm or more; a median diameter D50 as determined through a laser diffraction scattering method of 2.8 μm or more; a value obtained by dividing D90 by the mean particle size of 2.5 or more; and a value obtained by dividing D95 by the mean particle size of 3 or more. Subsequently, the pressed product was subjected to HIP at 1,850° C. in Table 1, to thereby yield a sintered product of tungsten. The thus-obtained tungsten sintered product was subjected to grinding by means of a lathe, to thereby form a tungsten target of a specific shape (diameter: 440 mm, thickness: 6 mm).

### Comparative Example 3

A tungsten powder (purity: 5N) having characteristics shown in Table 1 was hot-pressed at 1,650° C. as shown in Table 1. The characteristics of the powder were as follows: a mean particle size as determined through a laser diffraction scattering method of 3 μm or more; a median diameter D50 as determined through a laser diffraction scattering method of 2.8 μm or more; a value obtained by dividing D90 by the mean particle size of 2.5 or more; and a value obtained by dividing D95 by the mean particle size of 3 or more. Subsequently, the pressed product was subjected to HIP at 1,900° C. in Table 1, to thereby yield a sintered product of tungsten. The thus-obtained tungsten sintered product was subjected to grinding by means of a lathe, to thereby form a tungsten target of a specific shape (diameter: 440 mm, thickness: 6 mm).

### Comparative Example 4

A tungsten powder (purity: 5N) having characteristics shown in Table 1 was hot-pressed at 1,500° C. as shown in Table 1. The characteristics of the powder were as follows: a mean particle size as determined through a laser diffraction scattering method of 3 μm or more; a median diameter D50 as determined through a laser diffraction scattering method of 2.8 μm or more; a value obtained by dividing D90 by the mean particle size of 2.5 or more; and a value obtained by dividing D95 by the mean particle size of 3 or more. Subsequently, the pressed product was subjected to HIP at 1,850° C. in Table 1, to thereby yield a sintered product of tungsten. The thus-obtained tungsten sintered product was subjected to grinding by means of a lathe, to thereby form a tungsten target of a specific shape (diameter: 440 mm, thickness: 6 mm).

### Comparative Example 5

A tungsten powder (purity: 5N) having characteristics shown in Table 1 was hot-pressed at 1,500° C. as shown in Table 1. The characteristics of the powder were as follows: a mean particle size as determined through a laser diffraction scattering method of 3 μm or more; a median diameter D50 as determined through a laser diffraction scattering method of 2.8 μm or more; a value obtained by dividing D90 by the mean particle size of 2.5 or less; and a value obtained by dividing D95 by the mean particle size of 3 or more. Subsequently, the pressed product was subjected to HIP at 1,850° C. in Table 1, to thereby yield a sintered product of tungsten. The thus-obtained tungsten sintered product was subjected to grinding by means of a lathe, to thereby form a tungsten target of a specific shape (diameter: 440 mm, thickness: 6 mm).

### Comparative Example 6

A tungsten powder (purity: 5N) having characteristics shown in Table 1 was hot-pressed at 1,650° C. as shown in Table 1. The characteristics of the powder were as follows: a mean particle size as determined through a laser diffraction scattering method of 3 μm or more; a median diameter D50 as determined through a laser diffraction scattering method of 2.8 μm or less; a value obtained by dividing D90 by the mean particle size of 2.5 or less; and a value obtained by dividing D95 by the mean particle size of 3 or more. Subsequently, the pressed product was subjected to HIP at 1,850° C. in Table 1, to thereby yield a sintered product of tungsten. The thus-obtained tungsten sintered product was subjected to grinding by means of a lathe, to thereby form a tungsten target of a specific shape (diameter: 440 mm, thickness: 6 mm).

### Comparative Example 7

A tungsten powder (purity: 5N) having characteristics shown in Table 1 was hot-pressed at 1,450° C. as shown in Table 1. The characteristics of the powder were as follows: a mean particle size as determined through a laser diffraction scattering method of 3 μm or more; a median diameter D50 as determined through a laser diffraction scattering method of 2.8 μm or less; a value obtained by dividing D90 by the mean particle size of 2.5 or less; and a value obtained by dividing D95 by the mean particle size of 3 or more. Subsequently, the pressed product was subjected to HIP at 1,850° C. in Table 1, to thereby yield a sintered product of tungsten. The thus-obtained tungsten sintered product was subjected to grinding by means of a lathe, to thereby form a tungsten target of a specific shape (diameter: 440 mm, thickness: 6 mm).

### Comparative Example 8

A tungsten powder (purity: 5N) having characteristics shown in Table 1 was hot-pressed at 1,650° C. as shown in Table 1. The characteristics of the powder were as follows: a mean particle size as determined through a laser diffraction scattering method of 3 μm or more; a median diameter D50 as determined through a laser diffraction scattering method of 2.8 μm or less; a value obtained by dividing D90 by the mean particle size of 2.5 or less; and a value obtained by dividing D95 by the mean particle size of 3 or less. Subsequently, the pressed product was subjected to HIP at 1,850° C. in Table 1, to thereby yield a sintered product of tungsten. The thus-obtained tungsten sintered product was subjected to grinding by means of a lathe, to thereby form a tungsten target of a specific shape (diameter: 440 mm, thickness: 6 mm).

### Comparative Example 9

A tungsten powder (purity: 5N) having characteristics shown in Table 1 was hot-pressed at 1,450° C. as shown in Table 1. The characteristics of the powder were as follows: a mean particle size as determined through a laser diffraction scattering method of 3 μm or more; a median diameter D50 as determined through a laser diffraction scattering method of 2.8 μm or less; a value obtained by dividing D90 by the mean particle size of 2.5 or less; and a value obtained by dividing D95 by the mean particle size of 3 or less. Subsequently, the pressed product was subjected to HIP at 1,850° C. in Table 1, to thereby yield a sintered product of tungsten. The thus-obtained tungsten sintered product was subjected to grinding by means of a lathe, to thereby form a tungsten target of a specific shape (diameter: 440 mm, thickness: 6 mm).

### Comparative Example 10

A tungsten powder (purity: 5N) having characteristics shown in Table 1 was hot-pressed at 1,650° C. as shown in Table 1. The characteristics of the powder were as follows: a mean particle size as determined through a laser diffraction scattering method of 3 μm or less; a median diameter D50 as determined through a laser diffraction scattering method of 2.8 μm or less; a value obtained by dividing D90 by the mean particle size of 2.5 or less; and a value obtained by dividing D95 by the mean particle size of 3 or less. Subsequently, the pressed product was subjected to HIP at 1,850° C. in Table 1, to thereby yield a sintered product of tungsten. The thus-obtained tungsten sintered product was subjected to grinding by means of a lathe, to thereby form a tungsten target of a specific shape (diameter: 440 mm, thickness: 6 mm).

### Comparative Example 11

A tungsten powder (purity: 5N) having characteristics shown in Table 1 was hot-pressed at 1,450° C. as shown in Table 1. The characteristics of the powder were as follows: a mean particle size as determined through a laser diffraction scattering method of 3 μm or less; a median diameter D50 as determined through a laser diffraction scattering method of 2.8 μm or less; a value obtained by dividing D90 by the mean particle size of 2.5 or less; and a value obtained by dividing D95 by the mean particle size of 3 or less. Subsequently, the pressed product was subjected to HIP at 1,750° C. in Table 1, to thereby yield a sintered product of tungsten. The thus-obtained tungsten sintered product was subjected to grinding by means of a lathe, to thereby form a tungsten target of a specific shape (diameter: 440 mm, thickness: 6 mm).

The relative density, Vickers hardness, crystal grain size, oxygen content, carbon content, and pore features of each of the obtained targets were determined through the following procedures. Tables 2 and 3 show the results.

### (Relative Density)

Analytical samples (dimensions: 10×10 mm, thickness: 6 mm) were collected from each of the produced tungsten targets at positions of the center area, the edge area, and the midpoint between the center and the edge. A cross-section of each sample was polished and etched. Subsequently, the specific weight of each sample was calculated through Archimedes' principle, and the relative density was derived by reference to the theoretical density of tungsten (i.e., 19.3 g/cm³). The sum of the relative density measurements of the samples was divided by the number of the samples, to thereby determine the relative density of a tungsten target sample obtained in the present invention.

### (Vickers Hardness)

Analytical samples (dimensions: 10×10 mm, thickness: 6 mm) were collected from each of the produced tungsten targets at positions of the center area, the edge area, and the midpoint between the center and the edge. A cross-section of each sample was polished. Subsequently, the hardness of each sample was measured by means of a Vickers hardness meter “HM-200” (product of Mitutoyo Corporation). Measurement was conducted three times along a depth direction (intervals: 1 mm) at a load of 1 kg for 15 seconds, and the three measurements were averaged. The sum of the averaged hardness measurements of the samples was divided by the number of the samples, to thereby determine the hardness of a tungsten target sample obtained in the present invention.

Furthermore, the standard deviation in terms of hardness of a tungsten target was determined. Specifically, the sum of the standard deviations of the samples was divided by the number of the samples, to thereby determine the standard deviation of the tungsten target sample obtained in the present invention.

### (Crystal Grain Size)

Analytical samples (dimensions: 10×10 mm, thickness: 6 mm) were collected from each of the produced tungsten targets at positions of the center area, the edge area, and the midpoint between the center and the edge. A cross-section of each sample was polished and etched. Subsequently, the circle-equivalent diameter of each sample was measured by means of an optical microscope “Digital microscope VHX-6000” (product of Keyence Corporation). Specifically, images were taken along a depth direction (intervals: 1 mm), and the images were analyzed by image analysis software “Image-j,” to thereby obtain circle-equivalent diameters, which were then averaged. The sum of the averaged measurements of the test pieces was divided by the number of the pieces, to thereby determine the mean grain size of a tungsten target sample obtained in the present invention. Furthermore, the standard deviation in terms of crystal grain size of a tungsten target was determined. Specifically, the sum of the standard deviations of the samples was divided by the number of the samples, to thereby determine the standard deviation of the tungsten target sample obtained in the present invention.

### (Oxygen Content)

When a sintered product of tungsten was formed into a target, an analytical sample was collected. By use of the sample, the oxygen content of the formed target was determined. The oxygen content was determined by means of an analyzer (TC-600, product of LECO).

### (Carbon Content)

When a sintered product of tungsten was formed into a target, an analytical sample was collected. By use of the sample, the carbon content of the formed target was determined. The carbon content was determined by means of an analyzer (EMIA-320V, product of HORIBA Ltd.).

### (Pores)

Analytical samples (dimensions: 10×10 mm, thickness: 6 mm) were collected from each of the produced tungsten targets at positions of the center area, the edge area, and the midpoint between the center and the edge. A cross-section of each sample was polished. Subsequently, the sample was observed under an electron microscope (TM4000Plus, product of Hitachi High-Technologies), and two images were taken at a point along a depth direction (intervals: 1 mm). The images were analyzed by image analysis software “Image-j,” to thereby determine the area attributed to pores, whereby the size and number of pores in each sample were calculated. The sum of the measurements (i.e., the size and number of pores) of each sample was divided by the number of the pieces, to thereby determine the size and number of pores present in a tungsten target sample obtained in the present invention.

Next, film formation was performed in the below-described manner by use of each of the targets produced in the Examples and Comparative Examples. The specific resistance of the formed film was determined, and generation of particles was accessed in the following manner.

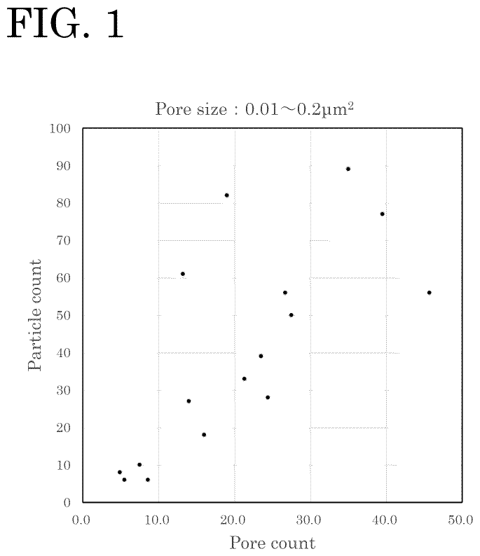

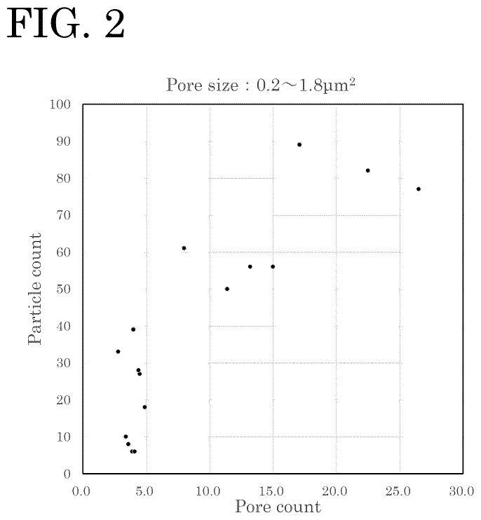

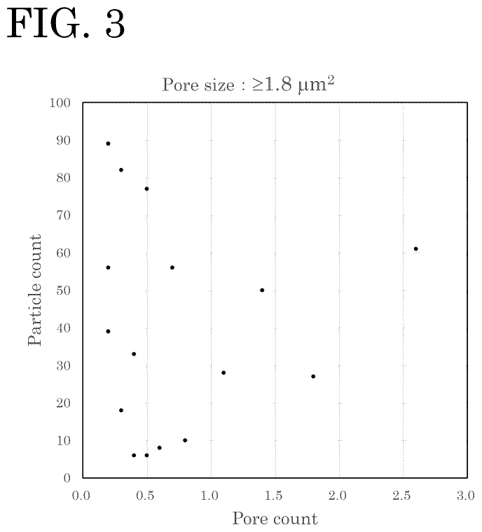

Table 3 shows the results of Examples 1 to 5 and Comparative Examples 1 to 11. FIGS. 1 to 3 each show the relationship between the number of pores having a specific size and the number of particles. In the graphs, a specific resistance of 11 μΩ·cm or lower is denoted with “O,” and a specific resistance higher than 11 μΩ·cm is denoted with “X.” When the specific resistance is 11 μΩ·cm or lower, an LSI wiring film having low resistance can be formed. As a result, a device with low power consumption can be produced.

### (Determination of Specific Resistance)

Each of the above-produced tungsten target was bonded to an aluminum alloy backing plate by the mediation of an In-base brazing filler metal, to thereby fabricate a sputtering cathode. The sputtering cathode was built in a sputtering apparatus (ENTRON (registered trademark), product of ULVAC, Inc.), and a tungsten thin film (thickness: 40 nm) was formed on a semiconductor wafer (diameter: 300 mm). Sputtering conditions were as follows: ultimate pressure: 1×10−5 Pa, discharge mode: DC, powder: 4 kW, gas source: Ar, gas flow: 150 sccm, film formation temperature: 200° C., sputtering time: 17 seconds, and target-wafer distance: 60 mm.

Nine points were chosen on the tungsten thin film formed on the wafer. At the 9 points, thickness was measured by means of “S-MAT2300” (product of TECHNORAYS), and sheet resistivity was measured by means of “OmniMap RS100” (product of KLA-Tencor), to thereby calculate the specific resistance (μΩ·cm) of the thin film. The specific resistance values were averaged, to thereby provide the specific resistance of the tungsten thin film.

### (Inspection of Particles)

The tungsten thin film (thickness: 40 mm), which had been subjected to the above specific resistance measurement, was inspected by means of a surface inspection apparatus (WM-10, product of TOPCON). The surface of the tungsten thin film on a semiconductor wafer (diameter: 300 mm) was observed, whereby the number of particles having a particle size of 0.1 μm or greater was counted.

TABLE 1

| | Powder morphology | | | | | |
|---|---|---|---|---|---|---|
| | Mean | | D90/mean | D95/mean | HP | HIP |
| | particle | D50 | particle | particle | temp. | conditions |
| | size (μm) | (μm) | size | size | (° C.) | (° C.) |
| Ex. 1 | 2.94 | 2.31 | 2.09 | 2.74 | 1450 | 1850 |
| Ex. 2 | 2.72 | 2.14 | 2.10 | 2.74 | 1400 | 1800 |
| Ex. 3 | 2.72 | 2.14 | 2.10 | 2.74 | 1400 | 1850 |
| Ex. 4 | 2.72 | 2.14 | 2.10 | 2.74 | 1450 | 1850 |
| Ex. 5 | 2.72 | 2.14 | 2.10 | 2.74 | 1500 | 1850 |
| Comp. 1 | 4.22 | 3.08 | 2.66 | 3.54 | 1750 | 1750 |
| Comp. 2 | 4.22 | 3.08 | 2.66 | 3.54 | 1750 | 1850 |
| Comp. 3 | 4.22 | 3.08 | 2.66 | 3.54 | 1650 | 1900 |
| Comp. 4 | 4.22 | 3.08 | 2.66 | 3.54 | 1500 | 1850 |
| Comp. 5 | 4.36 | 3.37 | 2.37 | 3.10 | 1500 | 1850 |
| Comp. 6 | 3.62 | 2.77 | 2.44 | 3.27 | 1650 | 1850 |
| Comp. 7 | 3.62 | 2.77 | 2.44 | 3.27 | 1450 | 1850 |
| Comp. 8 | 3.43 | 2.66 | 2.29 | 2.98 | 1650 | 1850 |
| Comp. 9 | 3.43 | 2.66 | 2.29 | 2.98 | 1450 | 1850 |
| Comp. 10 | 2.94 | 2.31 | 2.09 | 2.74 | 1650 | 1850 |
| Comp. 11 | 2.94 | 2.31 | 2.09 | 2.74 | 1450 | 1750 |

TABLE 2

| | | | | Crystal grain size | | | |
|---|---|---|---|---|---|---|---|
| | | Vickers | | Mean | 3σ/ | Oxygen | Carbon |
| | Relative | hardness | | grain | mean | content | content |
| | density | Av. | 3σ/ | size | particle | (ppm by | (ppm by |
| | (%) | (Hv) | av. | (μm) | size | mass) | mass) |
| Ex. 1 | 99.5 | 363 | 0.06 | 66.0 | 1.41 | 10 | 8 |
| Ex. 2 | 99.8 | 359 | 0.06 | 85.6 | 1.31 | 18 | 5 |
| Ex. 3 | 99.7 | 367 | 0.05 | 89.2 | 1.44 | 19 | 4 |
| Ex. 4 | 99.7 | 373 | 0.07 | 88.5 | 1.36 | 20 | 7 |
| Ex. 5 | 99.7 | 362 | 0.06 | 85.6 | 1.44 | 13 | 6 |
| Comp. 1 | 98.2 | 362 | 0.06 | 20.2 | 1.68 | 14 | 21 |
| Comp. 2 | 98.7 | 379 | 0.13 | 17.4 | 1.75 | 14 | 16 |
| Comp. 3 | 99.0 | 362 | 0.05 | 55.0 | 1.99 | 10 | 15 |
| Comp. 4 | 98.9 | 362 | 0.05 | 29.9 | 1.87 | 11 | 8 |
| Comp. 5 | 98.6 | 364 | 0.05 | 25.2 | 1.47 | 20 | 9 |
| Comp. 6 | 98.3 | 369 | 0.04 | 24.1 | 1.56 | 18 | 19 |
| Comp. 7 | 99.0 | 365 | 0.06 | 27.7 | 1.81 | 15 | 7 |
| Comp. 8 | 98.7 | 375 | 0.04 | 17.5 | 1.79 | 11 | 15 |
| Comp. 9 | 99.2 | 379 | 0.09 | 10.9 | 1.88 | 14 | 6 |
| Comp. 10 | 99.4 | 365 | 0.08 | 59.5 | 1.81 | 20 | 23 |
| Comp. 11 | 99.2 | 361 | 0.08 | 44.0 | 1.56 | 11 | 6 |

TABLE 3

| | Pores (counts) | | | Specific | |
|---|---|---|---|---|---|
| | 0.01- | 0.2- | | resistance ≤11 | Particles |
| | 0.2 μm² | 1.8 μm² | >1.8 μm² | μΩ · cm | of ≥0.1 μm |
| Ex. 1 | 16.0 | 4.9 | 0.3 | ◯ | 18 |
| Ex. 2 | 8.6 | 3.9 | 0.5 | ◯ | 6 |
| Ex. 3 | 4.9 | 3.6 | 0.6 | ◯ | 8 |
| Ex. 4 | 7.5 | 3.4 | 0.8 | ◯ | 10 |
| Ex. 5 | 5.5 | 4.1 | 0.4 | ◯ | 6 |
| Comp. 1 | 39.5 | 26.5 | 0.5 | X | 77 |
| Comp. 2 | 35.0 | 17.1 | 0.2 | X | 89 |
| Comp. 3 | 19.0 | 22.5 | 0.3 | X | 82 |
| Comp. 4 | 45.7 | 13.2 | 0.2 | ◯ | 56 |
| Comp. 5 | 13.2 | 8.0 | 2.6 | ◯ | 61 |
| Comp. 6 | 27.5 | 11.4 | 1.4 | X | 50 |
| Comp. 7 | 26.7 | 15.0 | 0.7 | ◯ | 56 |
| Comp. 8 | 23.5 | 4.0 | 0.2 | X | 39 |
| Comp. 9 | 21.3 | 2.8 | 0.4 | ◯ | 33 |
| Comp. 10 | 14.0 | 4.5 | 1.8 | X | 27 |
| Comp. 11 | 24.4 | 4.4 | 1.1 | ◯ | 28 |

As shown in Examples 1 to 5, by hot-pressing a tungsten powder having a mean particle size of 3 μm or less, a median diameter D50 of 2.8 μm or less, a ratio of D90 to the mean grain size of 2.5 or less, and a ratio of D95 to the mean grain size of 3 or less at 1,400° C. to 1,500° C., and subsequently, performing HIP at 1,800° C. to 1,850° C. (as shown in Table 1), there was successfully yielded a tungsten target having a relative density of 99% or higher, with the number of pores having a size of 0.01 μm² or more and less than 0.2 μm² being 20 or less; the number of pores having a size of 0.2 μm² or more and less than 1.8 μm² being 5 or less; and the number of pores having a size of 1.8 μm² or more being 1 or less, when the target was observed in an observation field of 0.15 mm². By use of the tungsten target, generation of particles can be suppressed, and a high-quality tungsten thin film can be consistently formed.

Also, in Examples 1 to 5, the hot press temperature was 1,500° C. or lower, and the carbon content of the target was sufficiently low. Thus, a thin film having a sufficiently low specific resistance (11 μΩ·cm or lower) was successfully formed.

In Comparative Example 1, the particle size of the tungsten powder was greater; the particle size distribution was wider; the HP temperature was higher; and the HIP temperature was lower, as compared with those of the Examples. As a result, the number of pores having a size of 0.01 μm² or more and less than 0.2 μm² and the number of pores having a size of 0.2 μm² or more and less than 1.8 μm² were greater. Thus, generation of particles occurred at high frequency, and difficulty was encountered in consistent film formation.

In addition, since the hot press temperature was higher, the carbon content of the target was not successfully controlled to a sufficiently low level. As a result, a thin film having a specific resistance of 11 μΩ·cm or lower failed to be formed.

In Comparative Example 2, the particle size of the tungsten powder was greater; the particle size distribution was wider; and the HP temperature was higher, as compared with those of the Examples. As a result, the number of pores having a size of 0.01 μm² or more and less than 0.2 μm² and the number of pores having a size of 0.2 μm² or more and less than 1.8 μm² were greater. Thus, generation of particles occurred at high frequency, and difficulty was encountered in consistent film formation.

In addition, since the hot press temperature was higher, the carbon content of the target was not successfully controlled to a sufficiently low level. As a result, a thin film having a specific resistance of 11 μΩ·cm or lower failed to be formed.

In Comparative Example 3, the particle size of the tungsten powder was greater; the particle size distribution was wider; the HP temperature was higher; and the HIP temperature was higher, as compared with those of the Examples. As a result, the number of pores having a size of 0.2 μm² or more and less than 1.8 μm² was greater. Thus, generation of particles occurred at high frequency, and difficulty was encountered in consistent film formation.

In addition, since the hot press temperature was higher, the carbon content of the target was not successfully controlled to a sufficiently low level. As a result, a thin film having a specific resistance of 11 μΩ·cm or lower failed to be formed.

In Comparative Example 4, the particle size of the tungsten powder was greater, and the particle size distribution was wider, as compared with those of the Examples. As a result, the number of pores having a size of 0.01 μm² or more and less than 0.2 μm² and the number of pores having a size of 0.2 μm² or more and less than 1.8 μm² were greater. Thus, generation of particles occurred at high frequency, and difficulty was encountered in consistent film formation.

However, since the hot press temperature was 1,500° C. or lower, the carbon content of the target was sufficiently low. Thus, a thin film having a sufficiently low specific resistance (11 μΩ·cm or lower) was successfully formed.

In Comparative Example 5, the particle size of the tungsten powder was greater, and the particle size distribution was wider, as compared with those of the Examples. As a result, the number of pores having a size of 0.2 μm² or more and less than 1.8 μm² was greater. Thus, generation of particles occurred at high frequency, and difficulty was encountered in consistent film formation.

However, since the hot press temperature was 1,500° C. or lower, the carbon content of the target was sufficiently low. Thus, a thin film having a sufficiently low specific resistance (11 μΩ·cm or lower) was successfully formed.

In Comparative Example 6, the particle size of the tungsten powder was greater; the particle size distribution was wider; and the HP temperature was higher, as compared with those of the Examples. As a result, the number of pores having a size of 0.01 μm² or more and less than 0.2 μm², the number of pores having a size of 0.2 μm² or more and less than 1.8 μm², and the number of pores having a size of 1.8 μm² or more were greater. Thus, generation of particles occurred at high frequency, and difficulty was encountered in consistent film formation.

In addition, since the hot press temperature was higher, the carbon content of the target was not successfully controlled to a sufficiently low level. As a result, a thin film having a specific resistance of 11 μΩ·cm or lower failed to be formed.

In Comparative Example 7, the particle size of the tungsten powder was greater, and the particle size distribution was wider, as compared with those of the Examples. As a result, the number of pores having a size of 0.01 μm² or more and less than 0.2 μm² and the number of pores having a size of 0.2 μm² or more and less than 1.8 μm² were greater. Thus, generation of particles occurred at high frequency, and difficulty was encountered in consistent film formation.

However, since the hot press temperature was 1,500° C. or lower, the carbon content of the target was sufficiently low. Thus, a thin film having a sufficiently low specific resistance (11 μΩ·cm or lower) was successfully formed.

In Comparative Example 8, the particle size of the tungsten powder was greater, and the HP temperature was higher, as compared with those of the Examples. As a result, the number of pores having a size of 0.01 μm² or more and less than 0.2 μm² was greater. Thus, generation of particles occurred at high frequency, and difficulty was encountered in consistent film formation.

In addition, since the hot press temperature was higher, the carbon content of the target was not successfully controlled to a sufficiently low level. As a result, a thin film having a specific resistance of 11 μΩ·cm or lower failed to be formed.

In Comparative Example 9, the particle size of the tungsten powder was greater, as compared with that of the Examples. As a result, the number of pores having a size of 0.01 μm² or more and less than 0.2 μm² was greater. Thus, generation of particles occurred at high frequency, and difficulty was encountered in consistent film formation.

However, since the hot press temperature was 1,500° C. or lower, the carbon content of the target was sufficiently low. Thus, a thin film having a sufficiently low specific resistance (11 μΩ·cm or lower) was successfully formed.

In Comparative Example 10, the HP temperature was higher, as compared with that of the Examples. As a result, the number of pores having a size of 1.8 μm² or more was greater. Thus, generation of particles occurred at high frequency, and difficulty was encountered in consistent film formation.

In addition, since the hot press temperature was higher, the carbon content of the target was not successfully controlled to a sufficiently low level. As a result, a thin film having a specific resistance of 11 μΩ·cm or lower failed to be formed.

In Comparative Example 11, the HIP temperature was lower, as compared with that of the Examples. As a result, the number of pores having a size of 0.01 μm² or more and less than 0.2 μm², and the number of pores having a size of 1.8 μm² or more were greater. Thus, generation of particles occurred at high frequency, and difficulty was encountered in consistent film formation.

However, since the hot press temperature was 1,500° C. or lower, the carbon content of the target was sufficiently low. Thus, a thin film having a sufficiently low specific resistance (11 μΩ·cm or lower) was successfully formed.

1.-8. (canceled)

9. A tungsten target formed of a sintered product of a tungsten powder, wherein
the target has a relative density of 99% or higher, and
a number of pores having a size of 0.01 μm² or more and less than 0.2 μm² is 20 or less;
the number of pores having a size of 0.2 μm² or more and less than 1.8 μm² is 5 or less; and the
number of pores having a size of 1.8 μm² or more is 1 or less, when the target is observed in an observation field of 0.15 mm².

10. The tungsten target according to claim 9, which has a mean value of Vickers hardness of 355 to 375.

11. The tungsten target according to claim 10, which has a ratio of a standard deviation 36 of Vickers hardness to the mean value of Vickers hardness of 0.07 or less.

12. The tungsten target according to claim 9, which has a mean grain size calculated on a basis of a circle-equivalent diameter of 150 μm or less.

13. The tungsten target according to claim 12, which has a mean crystal grain size calculated on a basis of a circle-equivalent diameter is 30 μm to 100 μm,

14. The tungsten target according to claim 9, which has a carbon content of 20 mass ppm or less, and an oxygen content of 30 mass ppm or less.

15. The tungsten target according to claim 12, which has a ratio of a standard deviation 3σ of the grain size calculated on the basis of the circle-equivalent diameter to the mean grain size of 1.5 or less.

16. A method for producing a tungsten target, the method comprising:
hot pressing a tungsten powder, wherein the powder has a mean particle size as determined through a laser diffraction scattering method of 3 μm or less and a median diameter D50 as determined through a laser diffraction scattering method of 2.8 μm or less, and
subsequently, sintering a pressed product through hot isostatic pressing at 1,800° C. to 1,850° C.

17. The tungsten target production method according to claim 16, wherein the tungsten powder has a ratio of D90 as determined through a laser diffraction scattering to the mean particle size as determined through a laser diffraction scattering method of 2.5 or less.

18. The tungsten target production method according to claim 17, wherein the tungsten powder has a ratio of D95 as determined through a laser diffraction scattering to the mean particle size as determined through a laser diffraction scattering method of 3.0 or less.

19. The tungsten target production method according to claim 16, wherein and a HP temperature and retention time are regulated to 1,400° C. to 1,500° C. and 600 minutes to 1,200 minutes, respectively.

20. The tungsten target production method according to claim 16, wherein a carbon content of the produced tungsten target is 20 mass ppm or less, an oxygen content is 30 mass ppm or less.
